(19) United States
(12) Patent Application Publication
(10) Pub. No.: US 2018/0226609 A1
(43) Pub. Date: Aug. 9, 2018

(54) MANUFACTURING METHOD FOR FLEXIBLE OLED AND FLEXIBLE OLED

(71) Applicant: Shenzhen China Star Optoelectronics Technology Co., Ltd., Shenzhen City (CN)

(72) Inventors: Wenjie Li, Shenzhen City (CN); Weijing Zeng, Shenzhen City (CN)

(21) Appl. No.: 15/121,038

(22) PCT Filed: Jul. 14, 2016
(86) PCT No.: PCT/CN2016/089956

§ 371 Date: Aug. 24, 2016

(30) Foreign Application Priority Data
Jun. 17, 2016 (CN) 201610439643.5

(51) Int. Cl. H01L 51/52; H01L 51/56; H01L 51/00; H01L 27/32

(52) U.S. Cl. CPC H01L 51/5253; H01L 51/56; H01L 2251/5338; H01L 27/32; H01L 51/0097

(57) ABSTRACT

The invention provides a manufacturing method for flexible OLED, using a magnetic substrate as the carrier substrate to magnetically attract the flexible magnetic thin film to be fixed, and then forming a polymer thin film on the flexible magnetic film, forming an OLED device on the polymer thin film, and then encapsulating the OLED device to complete manufacturing the flexible OLED. The method is simple, and achieves lossless separation between the flexible magnetic thin film and the magnetic substrates by degaussing the magnetic substrate. Moreover, the flexible magnetic thin film is preferably a metal thin film able to cut off moisture to improve the stability of OLED devices, and by encapsulating OLED device to further enhance the reliability of the OLED device performance. The flexible OLED of the invention is easy to manufacture and achieves excellent performance.

### BACKGROUND OF THE INVENTION

### 1. Field of the Invention

The present invention relates to the field of display, and in particular to a manufacturing method for flexible organic light-emitting diode (OLED) and flexible OLED.

### 2. The Related Arts

The organic light emitting diode (OLED) display, also called organic electroluminescent display, is the new trend of flat panel display technology. Because the OLED display provides the advantages of simple manufacturing process, low cost, low power-consumption, high illumination, wide operating temperature range, thin size, short response time, enabling full-color large display, easy to match integrated circuit (IC) driver, and enabling flexible display, the OLED is recognized as the technology with widest application prospect.

The flexible OLED panel has become an important research direction for organic luminous device. The flexible substrate is selected instead of the conventional glass substrate to achieve bendability. The common flexible substrate comprises metal thin films (aluminum foil or copper foil), and polymer thin films (e.g., polyethylene (PEI), etc.). Comparing the metal thin film to polymer thin film, the latter has good flexibility and light texture. When a polymer thin film is used as the flexible substrate to manufacture OLED devices, a polymer emulsion is evenly coated on the carrier substrate to prepare a polymer thin film, followed by manufacturing the OLED devices on the polymer thin film, and then peeling the polymer film from the carrier substrate after OLED device are manufactured.

FIG. 1 shows a schematic view of a known flexible substrate peeled from a carrier substrate. The common ways to peel are using a mechanical delamination method or a laser lift-off delamination method. The mechanical delamination method is simple, but is likely to cause warping of the flexible substrate. Moreover, the literature shows that a voltage drop will be produced between the polymer flexible substrate and the carrier substrate in the peeling process, and the accumulated charge will damage the thin film transistor (TFT) layer of the OLED devices. The laser lift-off delamination method can avoid the voltage drop problem described above, but the process is expensive. Therefore, it is desirable to devise a peeling method without damaging the flexible substrate and the TFT layer, which is particularly important for the development of a flexible display device.

Moreover, the organic luminous device is very sensitive to moisture and oxygen. The permeation of water and oxygen will greatly reduce the lifespan of the device. However, because the molecules of the polymer substrate has small molecular weight, and the structure is loose with more holes due to the loose cross-linking between the molecular chains, the possibility of moisture to permeate the device is increased.

### SUMMARY OF THE INVENTION

The object of the present invention is to provide a manufacturing method for flexible OLED, easy to use and by performing demagnetization on the carrier substrate to achieve the lossless separation of the flexible substrate and the carrier substrate and improve flexible OLED device performance.

Another object of the present invention is to provide a flexible OLED, easy to manufacture and achieving good performance.

To achieve the above object, the present invention provides a manufacturing method for flexible light-emitting diode (OLED), which comprises: Step 1: providing a magnetic substrate and a flexible magnetic thin film, the magnetic substrate having a controllable magnetism, the flexible magnetic thin film fixed to the magnetic substrate by magnetic attraction; Step 2: forming a polymer thin film on the flexible magnetic thin film; Step 3: forming an OLED device on the polymer thin film; Step 4: performing encapsulation on the OLED device.

The flexible magnetic thin film is a metal thin film; the polymer thin film is made of materials comprising one or more of polyimide, polyurethane, polyether sulfone resin, polyethylene naphthalate, polyvinyl alcohol, and polyether ether ketone.

The manufacturing method for flexible OLED further comprises: after Step 3 and before Step 4, or after Step 4, degaussing the magnetic substrate to rid of the magnetism from the magnetic substrate to remove the magnetic substrate from the flexible magnetic thin film.

Step 4 is to form an encapsulating thin film on the polymer thin film and the OLED device, the encapsulating thin film covers the top surface and the sides of the OLED device to accomplish encapsulating; the encapsulating thin film is a compound thin film comprising a plurality of organic thin film and a plurality of inorganic thin film stacked alternately.

Step 4 comprises: Step 41: coating a circle of adhesive material on the polymer thin film at a peripheral area around the OLED device, and disposing a desiccant on the polymer thin film at an area inside the adhesive material; Step 42: providing an encapsulating cover plate, attaching the encapsulating cover plate correspondingly to the polymer thin film at the side disposed with the adhesive material and the desiccant; and Step 43: solidifying the adhesive material to accomplish encapsulating the OLED device.

The adhesive material has a viscosity of 100-1000 Pa·s; the desiccant is a liquid desiccant, with a viscosity of 0.4-0.5 Pa·s, and in Step 41, the liquid desiccant is coated on the polymer thin film at an area inside the adhesive material; The cover encapsulating plate is a transparent flexible glass substrate; in Step 43, the solidifying the adhesive material comprises one or more of the UV irradiation curing and thermal curing.

The present invention also provides a flexible OLED, which comprises a flexible magnetic thin film, a polymer thin film disposed on the flexible magnetic thin film, an OLED device disposed on the polymer thin film, and an encapsulating thin film disposed on the OLED device and the polymer thin film and covering the top and the sides of the OLED device.

The flexible magnetic thin film is a metal thin film; the polymer thin film is made of materials comprising one or more of polyimide, polyurethane, polyether sulfone resin, polyethylene naphthalate, polyvinyl alcohol, and polyether ether ketone; and the encapsulating thin film is a compound thin film comprising a plurality of organic thin film and a plurality of inorganic thin film stacked alternately.

The present invention also provides a flexible OLED, which comprises a flexible magnetic thin film, a polymer thin film disposed on the flexible magnetic thin film, an OLED device disposed on the polymer thin film, an encapsulating cover plate disposed on the OLED device and the polymer thin film, an adhesive material disposed between the polymer thin film and the encapsulating cover plate and located at peripheral of the OLED device, and a desiccant disposed between the polymer thin film and the encapsulating cover plate and located at an area inside the adhesive material.

The flexible magnetic thin film is a metal thin film; the polymer thin film is made of materials comprising one or more of polyimide, polyurethane, polyether sulfone resin, polyethylene naphthalate, polyvinyl alcohol, and polyether ether ketone; the desiccant is a liquid desiccant with a viscosity of 0.4-0.5 Pa·s, and the encapsulating cover plate is a transparent flexible glass substrate.

Compared to the known techniques, the present invention provides the following advantages: the present invention provides a manufacturing method for flexible OLED, using a magnetic substrate as the carrier substrate to magnetically attract the flexible magnetic thin film to be fixed, and then forming a polymer thin film on the flexible magnetic film, forming an OLED device on the polymer thin film, and then encapsulating the OLED device to complete manufacturing the flexible OLED. The method is simple, and achieves lossless separation between the flexible magnetic thin film and the magnetic substrates by degaussing the magnetic substrate. Moreover, the flexible magnetic thin film is preferably a metal thin film able to cut off moisture to improve the stability of OLED devices, and by encapsulating OLED device to further enhance the reliability of the OLED device performance. The flexible OLED of the present invention is easy to manufacture and achieves excellent performance.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the known peeling approach of a flexible substrate from the carrier substrate;

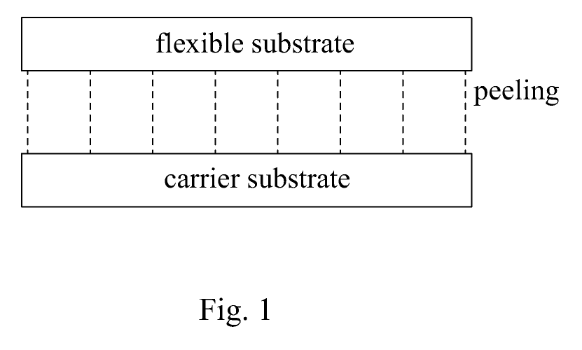

FIG. 2 is a schematic view showing the flowchart of the manufacturing method for flexible OLED provided by an embodiment of the present invention;

FIG. 3 is a schematic view showing Steps 1-3 of the manufacturing method for flexible OLED provided by an embodiment of the present invention;

FIG. 4 is a schematic view showing Step 4 of the manufacturing method for flexible OLED and the structure of the flexible OLED provided by a first embodiment of the present invention; and

FIG. 5 is a schematic view showing Step 4 of the manufacturing method for flexible OLED and the structure of the flexible OLED provided by a second embodiment of the present invention.

### DETAILED DESCRIPTION OF THE PREFERRED EMBODIMENTS

To further explain the technical means and effect of the present invention, the following refers to embodiments and drawings for detailed description.

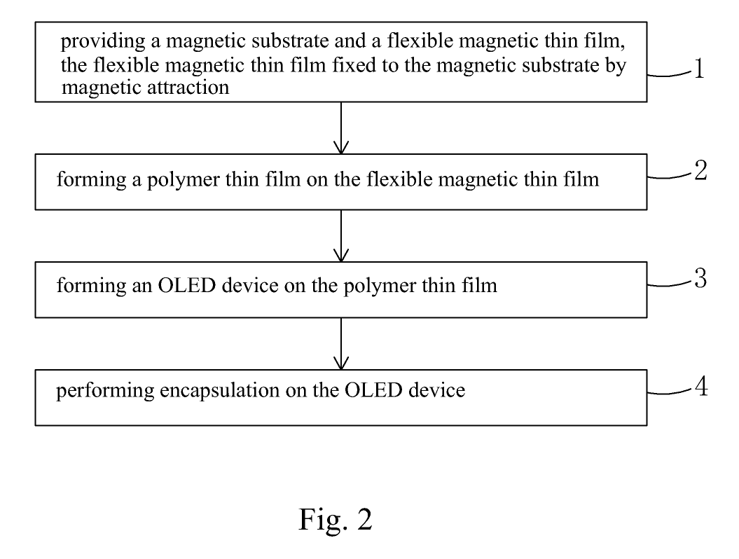

Refer to FIG. 2. The present invention provides a manufacturing method for flexible light-emitting diode (OLED), which comprises:

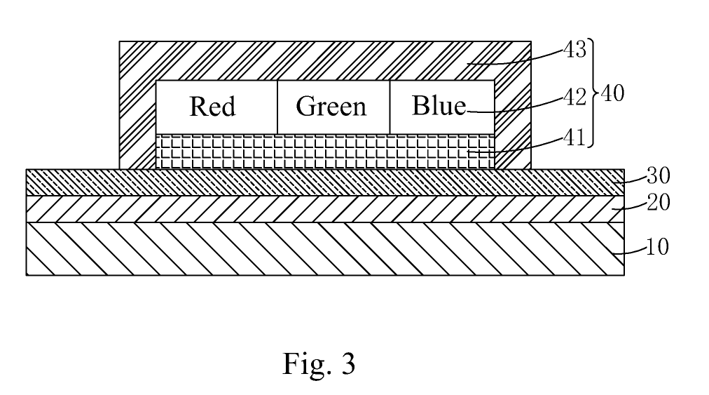

Step 1: referring to FIG. 3, providing a magnetic substrate 10 and a flexible magnetic thin film 20, the magnetic substrate 10 having a controllable magnetism, the flexible magnetic thin film 20 being fixed to the magnetic substrate 10 by magnetic attraction.

Preferably, the flexible magnetic thin film s a metal thin film. When the metal thin film has a thickness less than 100 μm, the good flexibility and stability can be achieved as well as ability to cut off moisture to provide effective protection for the OLED device to enhance stability and prolong lifespan.

Preferably, the metal thin film is made of invar.

Specifically, the thickness of the metal thin film is 10 μm-100 μm.

Specifically, the present invention does not place any restriction on the material for the magnetic substrate 10 as long as the magnetic is controllable. Preferably, the magnetic substrate 10 is an electromagnet, magnetic with electricity flowing while magnetism disappearing with the electricity being cut off.

Step 2: as shown in FIG. 3, forming a polymer thin film 20 on the flexible magnetic thin film 30.

Specifically, in Step 2, the polymer thin film 30 is formed on the flexible magnetic thin film 20 by a spin coating process or a chemical vapor deposition process. The thickness of the polymer thin film 30 is adjustable by controlling the concentration of the material, and the time and speed of spin coating or deposition.

Specifically, the polymer thin film 30 is made of materials comprising one or more of polyimide, polyurethane, polyether sulfone resin, polyethylene naphthalate, polyvinyl alcohol, and polyether ether ketone.

Preferably, the thickness of the polymer thin film 30 is 10 μm-200 μm.

In particular, the formation of the polymer thin film 30 on the flexible magnetic thin film 20 makes the flexible magnetic thin film 20 provide certain fixation and support to the polymer thin film 30.

Preferably, the polymer thin film 30 has the same area as the flexible magnetic thin film 20.

Step 3: as shown in FIG. 3, forming an OLED device 40 on the polymer thin film 40.

Specifically, the OLED device 40 comprises: a TFT layer 41, an organic light-emitting layer 42 disposed on the TFT layer 41, and a protection layer 43 disposed on the organic light-emitting layer 42.

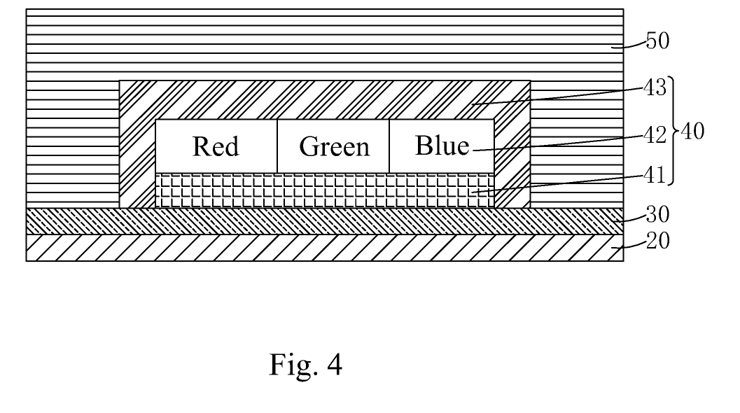

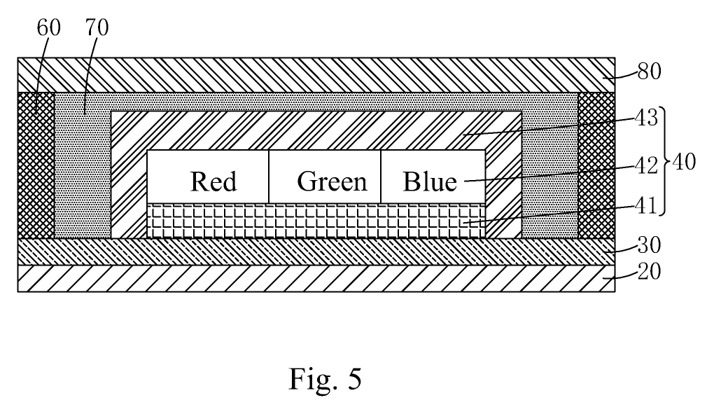

Step 4: as shown in FIG. 4 or 5, performing encapsulation on the OLED device 40.

Specifically, refer to FIG. 4. Step 4 may be: forming an encapsulating thin film 50 on the polymer thin film 30 and the OLED device 40. The encapsulating thin film 50 covers the top surface and the sides of the OLED device 40 to accomplish encapsulating the OLED device 40.

Specifically, the encapsulating thin film 50 is a compound thin film comprising a plurality of organic thin film and a plurality of inorganic thin film stacked alternately. Preferably, the inorganic thin films are made of silicon oxynitride, and the organic thin films are made of organic polymer. Specifically, the thickness of the encapsulating thin film 50 is 1 μm-50 μm.

Specifically, the encapsulating thin film 50 is manufactured by one or more of the following methods: evaporation, sputtering, and vapor deposition.

The encapsulating thin film 50 can realize the whole surface attachment in encapsulation to provide good ability to cut of moisture, prevent humidity form entering the OLED device 40 and prolong the lifespan of the device.

Alternatively, refer to FIG. 5. Step 4 may also comprise:

Step 41: coating a circle of adhesive material 60 on the polymer thin film 30 at a peripheral area around the OLED device 40, and disposing a desiccant 70 on the polymer thin film 30 at an area inside the adhesive material 60.

Preferably, the adhesive material has a viscosity of 100-1000 Pa·s.

Step 42: providing an encapsulating cover plate 80, attaching the encapsulating cover plate 80 correspondingly to the polymer thin film 30 at the side disposed with the adhesive material 60 and the desiccant 70.

Step 43: solidifying the adhesive material 60 to accomplish encapsulating the OLED device 40.

Specifically, the desiccant 70 is a liquid desiccant and in Step 41, the liquid desiccant is coated on the polymer thin film 30 at an area inside the adhesive material 60.

Preferably, the liquid desiccant has a viscosity of 0.4-0.5 Pa·s,

Preferably, the encapsulating cover plate 80 is a transparent flexible glass substrate.

Specifically, in Step 43, the solidifying the adhesive material 60 comprises one or more of the ultraviolet (UV) irradiation curing and thermal curing.

The above encapsulating method can prevent the moisture from entering the OLED device 40 through the device sides or surface with encapsulating cover plate 80 so as to prolong lifespan of the OLED device 40.

Specifically, the manufacturing method for flexible OLED further comprises: after Step 3 and before Step 4, or after Step 4, degaussing the magnetic substrate 10 to rid of the magnetism from the magnetic substrate 10 to remove the magnetic substrate 10 from the flexible magnetic thin film 20. When the magnetic substrate 10 is an electromagnet, the degaussing process on the magnetic substrate 10 is by cutting off the electricity.

Refer to FIG. 4. The present invention also provides a flexible OLED, which comprises a flexible magnetic thin film 20, a polymer thin film 30 disposed on the flexible magnetic thin film 20, an OLED device 40 disposed on the polymer thin film 30, and an encapsulating thin film 50 disposed on the OLED device 40 and the polymer thin film 30 and covering the top and the sides of the OLED device 40.

Specifically, the flexible magnetic thin film 20 and the polymer thin film 30 together form the flexible substrate for the OLED device 40 Preferably, the flexible magnetic thin film 20 and the polymer thin film 30 have the same area size.

Preferably, the flexible magnetic thin film 20 is a metal thin film, and the metal thin film is made of invar.

Specifically, the thickness of the metal thin film is 10 μm-100 μm.

Preferably, the polymer thin film 30 is made of materials comprising one or more of polyimide, polyurethane, polyether sulfone resin, polyethylene naphthalate, polyvinyl alcohol, and polyether ether ketone.

Preferably, the thickness of the polymer thin film 30 is 10 μm-200 μm.

In particular, the formation of the polymer thin film 30 on the flexible magnetic thin film 20 makes the flexible magnetic thin film 20 provide certain fixation and support to the polymer thin film 30.

Specifically, the OLED device 40 comprises: a TFT layer 41, an organic light-emitting layer 42 disposed on the TFT layer 41, and a protection layer 43 disposed on the organic light-emitting layer 42.

Specifically, the encapsulating thin film 50 is a compound thin film comprising a plurality of organic thin film and a plurality of inorganic thin film stacked alternately. Preferably, the inorganic thin films are made of silicon oxynitride, and the organic thin films are made of organic polymer. Specifically, the thickness of the encapsulating thin film 50 is 1 μm-50 μm.

Refer to FIG. 5. The present invention also provides a flexible OLED, which comprises a flexible magnetic thin film 20, a polymer thin film 30 disposed on the flexible magnetic thin film 20, an OLED device 40 disposed on the polymer thin film 30, an encapsulating cover plate 80 disposed on the OLED device 40 and the polymer thin film 30, an adhesive material 60 disposed between the polymer thin film 30 and the encapsulating cover plate 80 and located at peripheral of the OLED device 40, and a desiccant 70 disposed between the polymer thin film 30 and the encapsulating cover plate 80 and located at an area inside the adhesive material 60.

Specifically, the flexible magnetic thin film 20 and the polymer thin film 30 together form the flexible substrate for the OLED device 40 Preferably, the flexible magnetic thin film 20 and the polymer thin film 30 have the same area size.

Preferably, the flexible magnetic thin film 20 is a metal thin film, and the metal thin film is made of invar.

Specifically, the thickness of the metal thin film is 10 μm-100 μm.

Preferably, the polymer thin film 30 is made of materials comprising one or more of polyimide, polyurethane, polyether sulfone resin, polyethylene naphthalate, polyvinyl alcohol, and polyether ether ketone.

Preferably, the thickness of the polymer thin film 30 is 10 μm-200 μm.

In particular, the formation of the polymer thin film 30 on the flexible magnetic thin film 20 makes the flexible magnetic thin film 20 provide certain fixation and support to the polymer thin film 30.

Specifically, the OLED device 40 comprises: a TFT layer 41, an organic light-emitting layer 42 disposed on the TFT layer 41, and a protection layer 43 disposed on the organic light-emitting layer 42.

Specifically, the desiccant 70 is a liquid desiccant and the liquid desiccant completely fills the space between the polymer thin film 30 and the encapsulating cover plate 80 formed by the adhesive material 60.

Preferably, the liquid desiccant has a viscosity of 0.4-0.5 Pa·s,

Preferably, the encapsulating cover plate 80 is a transparent flexible glass substrate.

In summary, the present invention provides a manufacturing method for flexible OLED, using a magnetic substrate as the carrier substrate to magnetically attract the flexible magnetic thin film to be fixed, and then forming a polymer thin film on the flexible magnetic film, forming an OLED device on the polymer thin film, and then encapsulating the OLED device to complete manufacturing the flexible OLED. The method is simple, and achieves lossless separation between the flexible magnetic thin film and the magnetic substrates by degaussing the magnetic substrate. Moreover, the flexible magnetic thin film is preferably a metal thin film able to cut off moisture to improve the stability of OLED devices, and by encapsulating OLED device to further enhance the reliability of the OLED device performance. The flexible OLED of the present invention is easy to manufacture and achieves excellent performance.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A manufacturing method for flexible light-emitting diode (OLED), which comprises:
Step 1: providing a magnetic substrate and a flexible magnetic thin film, the magnetic substrate having a controllable magnetism, the flexible magnetic thin film fixed to the magnetic substrate by magnetic attraction;
Step 2: forming a polymer thin film on the flexible magnetic thin film;
Step 3: forming an OLED device on the polymer thin film; and
Step 4: performing encapsulation on the OLED device.

2. The manufacturing method for flexible OLED as claimed in claim 1, wherein the flexible magnetic thin film is a metal thin film; the polymer thin film is made of materials comprising one or more of polyimide, polyurethane, polyether sulfone resin, polyethylene naphthalate, polyvinyl alcohol, and polyether ether ketone.

3. The manufacturing method for flexible OLED as claimed in claim 1, further comprises: after Step 3 and before Step 4, or after Step 4, degaussing the magnetic substrate to rid of the magnetism from the magnetic substrate to remove the magnetic substrate from the flexible magnetic thin film.

4. The manufacturing method for flexible OLED as claimed in claim 1, wherein Step 4 is to form an encapsulating thin film on the polymer thin film and the OLED device, the encapsulating thin film covers the top surface and the sides of the OLED device to accomplish encapsulating; the encapsulating thin film is a compound thin film comprising a plurality of organic thin film and a plurality of inorganic thin film stacked alternately.

5. The manufacturing method for flexible OLED as claimed in claim 1, wherein Step 4 comprises:
Step 41: coating a circle of adhesive material on the polymer thin film at a peripheral area around the OLED device, and disposing a desiccant on the polymer thin film at an area inside the adhesive material;
Step 42: providing an encapsulating cover plate, attaching the encapsulating cover plate correspondingly to the polymer thin film at the side disposed with the adhesive material and the desiccant; and
Step 43: solidifying the adhesive material to accomplish encapsulating the OLED device.

6. The manufacturing method for flexible OLED as claimed in claim 5, wherein the adhesive material has a viscosity of 100-1000 Pa·s;
the desiccant is a liquid desiccant, with a viscosity of 0.4-0.5 Pa·s, and in Step 41, the liquid desiccant is coated on the polymer thin film at an area inside the adhesive material;
the cover encapsulating plate is a transparent flexible glass substrate;
in Step 43, the solidifying the adhesive material comprises one or more of the UV irradiation curing and thermal curing.

7. A flexible organic light-emitting diode (OLED), which comprises: a flexible magnetic thin film, a polymer thin film disposed on the flexible magnetic thin film, an OLED device disposed on the polymer thin film, and an encapsulating thin film disposed on the OLED device and the polymer thin film and covering the top and the sides of the OLED device.

8. The flexible OLED as claimed in claim 7, wherein The flexible magnetic thin film is a metal thin film; the polymer thin film is made of materials comprising one or more of polyimide, polyurethane, polyether sulfone resin, polyethylene naphthalate, polyvinyl alcohol, and polyether ether ketone; and the encapsulating thin film is a compound thin film comprising a plurality of organic thin film and a plurality of inorganic thin film stacked alternately.

9. A flexible organic light-emitting diode (OLED), which comprises: a flexible magnetic thin film, a polymer thin film disposed on the flexible magnetic thin film, an OLED device disposed on the polymer thin film, an encapsulating cover plate disposed on the OLED device and the polymer thin film, an adhesive material disposed between the polymer thin film and the encapsulating cover plate and located at peripheral of the OLED device, and a desiccant disposed between the polymer thin film and the encapsulating cover plate and located at an area inside the adhesive material.

10. The flexible OLED as claimed in claim 9, wherein the flexible magnetic thin film is a metal thin film; the polymer thin film is made of materials comprising one or more of polyimide, polyurethane, polyether sulfone resin, polyethylene naphthalate, polyvinyl alcohol, and polyether ether ketone; the desiccant is a liquid desiccant with a viscosity of 0.4-0.5 Pa·s, and the encapsulating cover plate is a transparent flexible glass substrate.
